(19) United States
(12) Patent Application Publication
(10) Pub. No.: US 2019/0131922 A1
(43) Pub. Date: May 2, 2019

(54) POWER SUPPLY APPARATUS EMPLOYING SOLAR PANELS

(71) Applicant: Alex Quinn, Red Bud, IL (US)

(72) Inventor: Alex Quinn, Red Bud, IL (US)

(21) Appl. No.: 15/794,108

(22) Filed: Oct. 26, 2017

(51) Int. Cl. H02S 40/38; H02J 7/35; H02M 7/42; H01L 31/042

(52) U.S. Cl. CPC H02S 40/38; H01L 31/042; H02M 7/42; H02J 7/355

(57) ABSTRACT

A single unit apparatus (10) for supplying electrical energy to large appliances, electrically operated equipment, and electrically operated systems. A power post (12) extends vertically upwardly from the ground and supports a plurality of solar panels (16) for collecting solar energy. A controller (20) controls the flow of electrical energy from the solar panels to a storage battery (22). The stored energy is supplied through a DC-AC inverter (24) to an electrical outlet (26) to which the large appliance, electrically operated piece of equipment, or electrically operated system is connected so receive electrical power from the apparatus. All of the components are mounted to or in the power post so that the apparatus does not require the connection of disparate elements in order to function.

### CROSS REFERENCE TO RELATED APPLICATIONS

None

### STATEMENT REGARDING FEDERALLY SPONSORED RESEARCH OR DEVELOPMENT

N/A

### BACKGROUND OF THE INVENTION

This invention relates to the supply of electrical energy to large consumer appliances and electrically operated equipment and systems; and, more particularly, to a power supply apparatus utilizing solar panels for producing electrical energy. The apparatus has a sufficiently large energy storage capability enabling it to function as a viable energy source for such appliances, equipment, and systems.

Solar panels are comprised of photovoltaic cells which absorb light energy (photons) generated by the sun and convert this absorbed solar energy, using the photovoltaic effect, to electricity. One benefit of solar energy based power sources is the capability of providing electricity to places (homes, factories, stores, etc.) which are either not part of an electric utilities power distribution grid, or where access to the grid is prohibitively expensive.

While there are many devices currently in use to charge or power small, typically portable electronic devices found in everyday use; there is no similar type apparatus for powering larger appliances or electrically operated equipment or systems.

It will be understood by those skilled in the art that while the small, portable devices operate off of direct current (DC), larger appliances, equipment and systems are powered by an alternating current (AC). At this time, many products or systems for supplying electricity and which use solar panels are not, for various reasons, conveniently housed as a single unit, but rather the components are deployed or spread out over several pieces and so require interconnections between them. This can result in problems in making interconnections between the various parts, possible damage to a part which may render the overall system inoperable, etc. In addition, these existing products are not equipped with, for example, an inverter which would otherwise enable the incorporation of conventional AC outlets to which AC powered appliances, equipment, or systems are connected.

To address this problem, the current invention is directed to a self-contained, all-in -one, weather resistant solar powered apparatus which addresses the problems described above.

### BRIEF SUMMARY OF THE INVENTION

The present invention is directed to a single unit apparatus using solar panels as a source for producing electrical energy. The apparatus comprises a stationary, self-contained power post that is either anchored to the ground or supported on a base or pedestal to prevent it from tipping over. A sleeve fitting over the post includes shelving which enables users to easily access electrical components stored in the apparatus simply by lifting the sleeve off the post. The sleeve includes vents for water and heat dissipation, and the build -up of gases within the apparatus.

A plurality of solar panels is installed on a mount and positioned either over the top of the post or to the sides of the post; the panels being installed in a predetermined arrangement to most efficiently collects or absorb solar energy based on the location of the apparatus. The solar panel, in conjunction with a controller, batteries, and an inverter, produces sufficient electrical energy to power appliances and electrically operated equipment and systems. All of these components are mounted or installed in the power post and so do not require the connection of disparate elements to complete the apparatus or affect its functionality.

Other objects and features will be in part apparent and in part pointed out hereinafter.

### BRIEF DESCRIPTION OF THE SEVERAL VIEWS OF THE DRAWINGS

The accompanying figures, together with detailed description which follows, form part of the specification and illustrate the various embodiments described in the specification.

FIG. 1 is an elevation view of a first embodiment of the apparatus in which solar panels are mounted on top of the structure; and,

FIG. 2 is an elevation view of a second embodiment of the apparatus in which solar panels are mounted to the sides of the structure.

Corresponding reference characters indicate corresponding parts throughout the several views of the drawings.

### DETAILED DESCRIPTION OF INVENTION

The following detailed description illustrates the invention by way of example and not by way of limitation. This description clearly enables one skilled in the art to make and use the invention, and describes several embodiments, adaptations, variations, alternatives and uses of the invention, including what is presently believed to be the best mode of carrying out the invention. Additionally, it is to be understood that the invention is not limited in its application to the details of construction and the arrangement of components set forth in the following description or illustrated in the drawings. The invention is capable of other embodiments and of being practiced or carried out in various ways. Also, it will be understood that the phraseology and terminology used herein is for the purpose of description and should not be regarded as limiting.

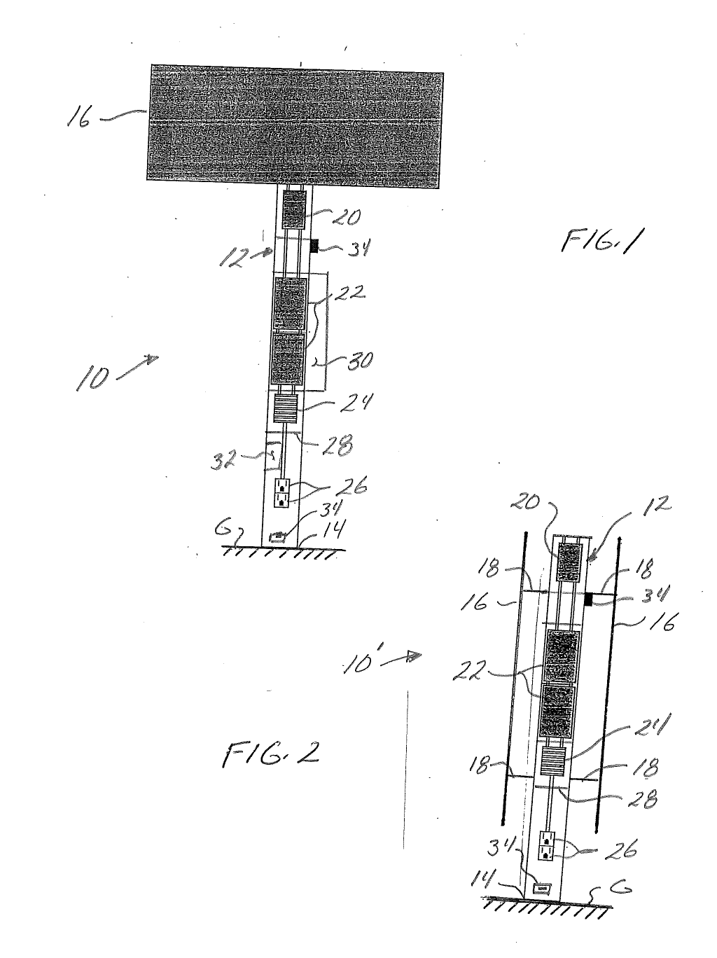

Referring to the drawings, an apparatus 10 (FIG. 1) or 10′ (FIG. 2) of the present invention first includes a stationary, self-contained power post 12. Post 12 can be a circular or rectangular post which projects vertically upwardly and the base 14 of which is affixed to the ground G or a base (not shown) so as to anchor the post in place and prevent it from tipping over even in strong wind conditions. Post 12 is of a metal, plastic or composite metal and plastic construction suitable for an all-weather installation and operation. The overall dimensions, including height, of the post are determined by the equipment and components, as described hereinafter, stored or contained in the post. A further determinant as to the size of post 12 is the construction of solar panels 16 supported by the post. As shown in FIG. 1, at least one solar panel 16 is mounted atop post 12; while, as shown in FIG. 2, solar panels 16 are supported on the sides of the post by brackets 18. Those skilled in art will understand that the number of solar panels 16 shown in the drawings is illustrative only.

With regard to the solar panels 16, it will further be understood by those skilled in the art that the solar panels may be arranged over or about post 12 in arrays other than those shown in the drawings. In addition, the size and shape of the solar panels can be other as shown in the drawings. The construction of the solar panels, the adjustable mounts (not shown) on which they are installed, and location about the top or sides of post 10 do not form part of the invention and are not described. It will be understood, however, that the solar panels will be positioned so as to most efficiently collect solar energy given the time of day, weather conditions and season of the year. What is important is that the electricity generated by the solar panels is sufficient that those appliances, electrically operated equipment, and systems powered by apparatus 10 have enough energy available to them that they can conveniently operate to perform the functions for which they were designed.

Post 10 has installed within it a controller 20 and one or more electrical storage batteries 22. As shown in the drawings, controller 20 is intermediate the solar panels and the batteries. Controller 20 controls flow of electrical energy between the solar panels and the batteries. If, for example, the controller senses that the batteries are fully charged, it will stop flow of electricity between the solar panels and the batteries. Further, if the controller senses that a load voltage is too high for the storage batteries to handle, it will serve to disconnect the batteries from the load.

Mounted within post 12, besides controller 20 and the one or more storage batteries 22, are a DC to AC inverter 24, and one or more electrical outlets 26. Although not shown, the electrical outlets have weatherproof covers fitted over them. Again, those skilled in art will understand that the number of these components shown in the drawings is illustrative only. Because all of these components are mounted or installed in power post 12, apparatus 10 does not require the connection of disparate elements to complete the apparatus or affect its functionality.

Constructed within post 12 is a shelving system 28 for the installation of and access to the various components. The shelving system includes removable panels 30, see FIG. 1, by which the components are accessed for repair, replacement, adjustments, etc.

In operation, flow of solar energy collected by the solar panels 16 is controlled by controller 20. The electricity produced by the solar panels then charges the batteries 22 which store the energy until needed. When a power cord for an appliance, for example, is connected to one of the electrical outlets 26, and the appliance is turned “on”, power from the batteries is provided to inverter 24 which converts the energy from DC to, for example, 110 VAC. It will be understood that inverter 24 may be capable of producing voltages higher than that of 110 VAC, or that the electrical output of the inverter is supplied to the primary side of a step-up transformer 32, see FIG. 1, with the voltage available on the secondary side of the transformer being the higher voltage.

Finally, a plurality of vents 34 are incorporated in post 12. The vents allow for air circulation through the apparatus to prevent a heat buildup which could affect operation of the components, allow drainage of any water which might otherwise accumulate, and exhaust any gases, as well as dirt and dust particles that might otherwise buildup.

In view of the above, it will be seen that the several objects and advantages of the present disclosure have been achieved and other advantageous results have been obtained.

Having thus described the invention, what is claimed and desired to be secured by Letters Patent is:

1. A single unit apparatus for supplying electrical energy to large appliances, and electrically operated equipment and systems, comprising:
a power post extending vertically upwardly from the ground;
a plurality of solar panels supported by the post for collecting solar energy;
at least one storage battery mounted within the post for storing the solar energy collected by the solar panels; and,
at least one electrical outlet installed in the post and to which the stored electrical energy is supplied from the storage battery, a large appliance, an electrically operated piece of equipment, or an electrically operated system being connected to the outlet to receive electrical power from the apparatus.

2. The apparatus of claim 1 in which the solar panels are installed generally horizontally above the top of the post.

3. The apparatus of claim 1 in which the solar panels are installed generally vertically along the sides of the post.

4. The apparatus of claim 1 further including a controller installed within the post for controlling the supply of solar energy collected by the solar panels to the at least one storage battery.

5. The apparatus of claim 1 further including a DC-AC inverter mounted within the post and interposed between the storage battery and electrical outlet for AC energy to be supplied to the large appliance, electrically operated piece of equipment, or electrically operated system.

6. The apparatus of claim 1 in which the post is anchored to the ground or mounted on a pedestal to prevent the post from tipping over.

7. The apparatus of claim 1 further including a shelving system constructed within the post for installation of the controller, storage battery, inverter, and electrical outlet.

8. The apparatus of claim 7 in which the shelving system includes removable panels by which controller, storage battery, inverter, and electrical outlet can be accessed for repair, replacement, and adjustments.

9. The apparatus of claim 1 further including a plurality of vents incorporated in the post, the vents allowing for air circulation through the apparatus to prevent a heat buildup which could affect operation of the controller, storage battery, inverter, and electrical outlet, allow drainage of any water which might otherwise accumulate, and exhaust any gases, as well as dirt and dust particles that might otherwise buildup within the apparatus.
